(19) United States
(12) Patent Application Publication
(10) Pub. No.: US 2007/0155106 A1
(43) Pub. Date: Jul. 5, 2007

(54) METHOD OF MANUFACTURING CMOS IMAGE SENSOR

(76) Inventor: Jae Hee Kim, Gyeonggi-do (KR)

Correspondence Address: SHERR & NOURSE, PLLC, 620 HERNDON PARKWAY, SUITE 200, HERNDON, VA, 20170, US

(21) Appl. No.: 11/614,674

(22) Filed: Dec. 21, 2006

(30) Foreign Application Priority Data
Dec. 28, 2005 (KR) 10-2005-0132337

(51) Int. Cl. H01L 21/336

(52) U.S. Cl. 438/292; 257/E21.352

(57) ABSTRACT

Disclosed is a method of manufacturing a CMOS image sensor. The method reduces a difference in the height of the interconnection layers over the logic area and pixel array area. At the same time, the method also provides a closer proximity between the micro-lenses and the pixel array. A semiconductor substrate has a pixel array area and a logic circuit area. A lower interconnection is formed over the semiconductor substrate. An interlayer dielectric layer is formed over the lower interconnection. A via hole is formed by removing a portion of the interlayer dielectric layer in the logic circuit area. An upper interconnection is formed by filling the first via hole with a metal, then planarizing the surface.

The present application claims priority under 35 U.S.C. 119 and 35 U.S.C. 365 to Korean Patent Application No. 10-2005-0132337 (filed on Dec. 28, 2005), which is hereby incorporated by reference in its entirety.

### BACKGROUND

In general, image sensors are semiconductor devices for converting an optical image into an electrical signal. Among the image sensors, the CMOS image sensor is a device employing a switching mode to sequentially detect an output by providing photodiodes corresponding to the number of pixels through a CMOS technology that uses peripheral devices, such as a control circuit and a signal processing circuit.

Studies and research on image sensor fabrication techniques have improved photosensitivity.

The CMOS image sensor is composed of a pixel array unit including photodiodes for sensing light and a CMOS logic circuit for processing the detected light into electrical signals, to convert them into data. In order to improve photosensitivity, either the area occupied by the photodiodes must be increased, or a photo-gathering technology must be used to collect more light in the photodiode area by focusing the light path and forming a micro-lens over the upper portion of the photodiodes.

CMOS image sensors are divided into 3T-type CMOS image sensors, 4T-type CMOS image sensors, and 5T-type CMOS image sensors in accordance with the number of transistors. The 3T-type CMOS image sensor is composed of one photodiode and 3 transistors. The 4T-type CMOS image sensor is composed of 4 transistors. An equivalent circuit and a layout for a unit pixel of the 3T-type CMOS image sensor will be described as follows.

FIG. 1 is an equivalent circuit diagram of a 3T CMOS image sensor, and FIG. 2 is a layout diagram illustrating a unit pixel of the 3T MOS image sensor.

The unit pixel of the 3T-type CMOS image sensor, as illustrated in FIG. 1, is composed of one photodiode and three nMOS transistors T1, T2, and T3. The cathode of the photodiode PD is connected to the drain of the first nMOS transistor T and the gate of the second nMOS transistor T2.

In addition, sources of the first and second nMOS transistors T1 and T2 are connected to a power line feeding a reference voltage VR, and a gate of the first nMOS transistor T1 is connected to a reset line feeding a reset signal RST.

Also, the source of the third nMOS transistor T3 is connected to the drain of the second nMOS transistor. The drain of the third nMOS transistor T3 is connected to a reading circuit (not shown) through a signal line). The gate of the third nMOS transistor T3 is connected to a column selection line to which the selection signal SLCT is supplied.

Therefore, the first nMOS transistor T1 is referred to as a reset transistor Rx, the second nMOS transistor T2 is referred to as a drive transistor Dx, and the third nMOS transistor T3 is referred to as a selection transistor Sx.

In the unit pixel of the 3T CMOS image sensor, as illustrated in FIG. 2, an active region 10 is defined so that one photodiode 20 is formed in a wide part of the active region 10 and that the gate electrodes 120, 130, and 140 of the overlapping three transistors are formed in the remaining part of the active region 10.

That is, the reset transistor Rx is formed by the gate electrode 120, the drive transistor Dx is formed by the gate electrode 130, and the selection transistor Sx is formed by the gate electrode 140.

Here, dopants are implanted into the part excluding the lower parts of the gate electrodes 120, 130, and 140 in the active region 10 of the transistor, so that the source and drain regions of the transistors are formed.

Accordingly, supply voltage Vdd is applied to the source/drain area between the reset transistor Rx and the drive transistor Dx, and a source/drain area formed at one side of the select transistor Sx is connected to a reading circuit (not shown).

Although not shown in the drawing, the gate electrodes 120, 130, and 140 are connected to the signal lines and each signal line includes a pad at one end to be connected to an external driving circuit.

Hereinafter, a method of manufacturing a CMOS image sensor will be described with reference to the attached drawings.

FIGS. 3A to 3C are sectional views showing a method of manufacturing the CMOS image sensor.

As illustrated in FIG. 3A, an oxide layer is deposited over a semiconductor substrate (not shown) divided into a pixel array unit (P) and a logic circuit unit (L) to form an interlayer insulating layer 61. A chemical mechanical polishing (CMP) process is performed to planarize the surface of the interlayer insulating layer 61.

Various interconnections, transistors, and photodiodes are provided on the semiconductor substrate.

Then, a metal such as aluminum may be sputtered over the interlayer insulating layer 61. The deposited metal may be patterned by a photolithography process to form a pad electrode 53 in the logic circuit unit L for supplying power.

The metal interconnection 53 is confined within the logic circuit unit L. Since the metal interconnection 53 may be a power line that receives a signal from the external driving circuit, the metal interconnection 53 is made relatively thick.

For instance, metal interconnections 51 and 52 provided between the interlayer dielectric layers may be about 1500 Å to 4000 Å thick, but the metal interconnection 53 confined within the logic circuit unit for supplying power or other functions external to the chip may be about 5000 Å to 9000 Å thick.

Then, as shown in FIG. 3B, a first oxide layer 62 is deposited over the entire surface of the substrate including the metal interconnection 53. At this time, in order to remove a step difference between the pixel array unit and the logic circuit unit, the first oxide layer 62 is formed to be thick.

Subsequently, the first oxide layer 62 is polished in a CMP process. To prevent the metal interconnection 53 from being polished, the CMP process is stopped well above the metal interconnection, leaving about 3,000 Å to 5,000 Å of oxide layer 62 over the metal interconnection. Therefore, after polishing, the first oxide layer 62 formed over the interlayer dielectric layer 61 may have a thickness of about 8,000 Å to 14,000 Å.

Finally, a nitride layer 63 and a second oxide layer 64 are sequentially deposited over the first oxide layer 62, thereby forming a protective layer. The protective layer formed over the metal interconnection 53 is etched to form a via hole 72 for exposing the metal interconnection 53. The metal interconnection 53 is electrically connected to the external driving circuit through the via hole 72.

However, the metal interconnections of CMOS image sensors are made of multiple layers electrically connected to each other. In the case of a three layer metal structure, two metal interconnections are formed over the pixel array unit and three metal interconnections are formed over the logic circuit. In addition, in the case of a four layer metal structure, three metal interconnections are formed over the pixel array unit and four metal interconnections are formed over the logic circuit unit. In other words, the logic circuit unit has one more metal interconnection layer as compared with the pixel array.

However, since the logic circuit has one more metal interconnection layer, a step difference may occur between the pixel array unit and the logic circuit unit. Since the uppermost metal interconnection is used for power supply, the uppermost metal interconnection is made thicker to lower resistance, further increasing the step height between the pixel array unit and the logic circuit unit.

A step difference between the pixel array unit and the logic circuit unit makes the CMP process on the protective layer more difficult. In addition, surface uniformity may not be easily achieved even after the CMP process is performed.

Therefore, the protective layer is made thick to minimize the step difference caused by the metal interconnection layer 53. However, this means the vertical height from the pixel unit to a micro-lens formed over the protective layer may increase, so that sensitivity of the CMOS image sensor is degraded and optical cross-talk is increased.

### SUMMARY

Embodiments relate to a method of manufacturing a CMOS image sensor, which can significantly reduce the vertical height of the micro-lens in the light receiving unit by forming an uppermost metal interconnection of a logic circuit unit through a damascene process and forming a protective layer over the uppermost metal interconnection with a minimum thickness, thereby improving sensitivity and reducing optical cross-talk.

### BRIEF DESCRIPTION OF THE DRAWINGS

FIG. 1 is an equivalent circuit diagram of a 3T CMOS image sensor according to a related art;

FIG. 2 is a layout diagram illustrating a unit pixel of a 3T MOS image sensor according to the related art;

FIGS. 3A to 3C are sectional views showing a method of manufacturing a CMOS image sensor according to a related art; and

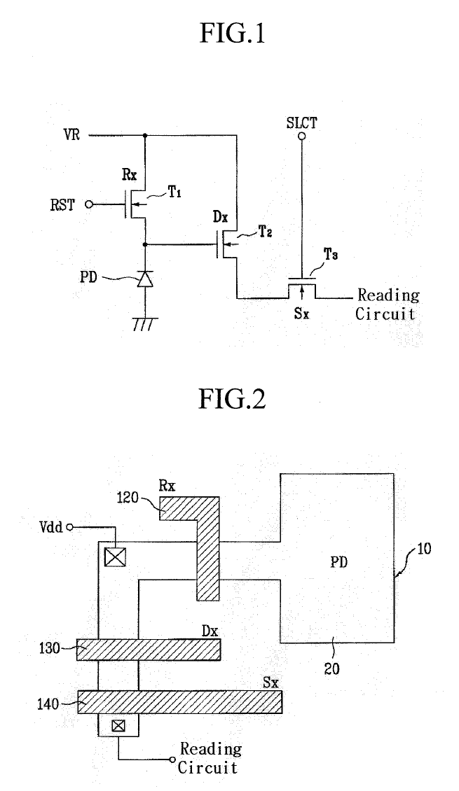

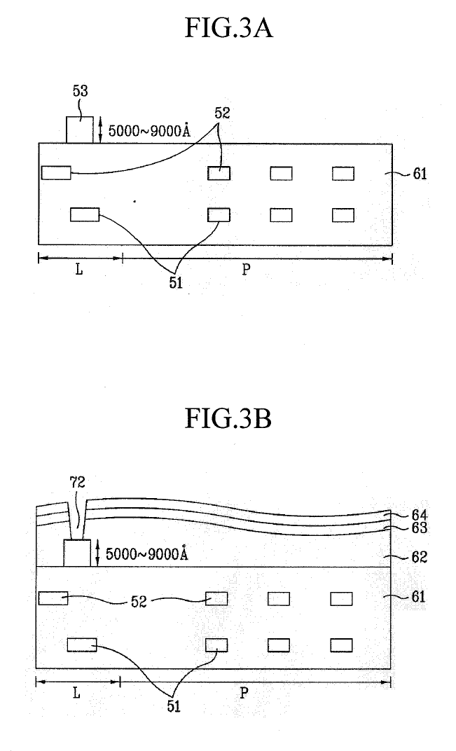

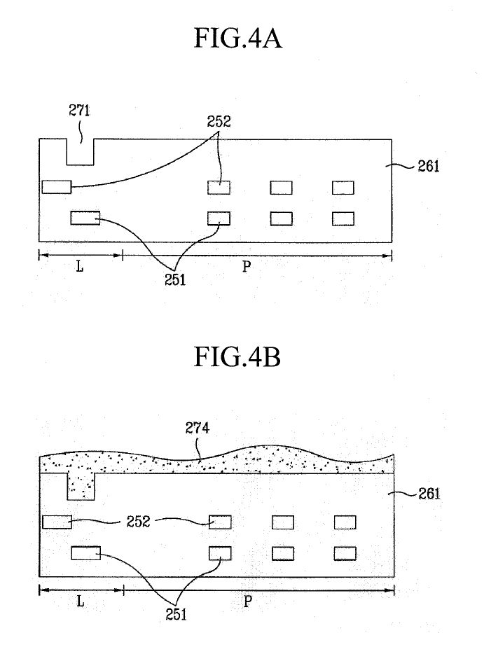

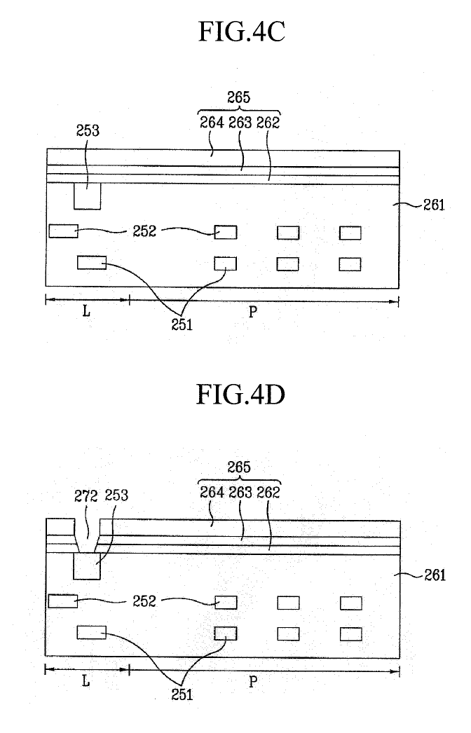

Example FIGS. 4A to 4D are sectional views illustrating the procedure for manufacturing a CMOS image sensor according to embodiments.

### DETAILED DESCRIPTION

As shown in FIG. 4A, an oxide layer is deposited over a semiconductor substrate 231, which is divided into a pixel array area P and a logic circuit area L, to form an interlayer dielectric layer 261. Then, a chemical mechanical polishing (CMP) process is performed on the interlayer dielectric layer 261 to planarize the surface.

Lower interconnections 251 and 252 are formed as a multiple layer structure over the semiconductor substrate 231 and are electrically connected to each other through contact plugs. Although not shown in the drawing, R, G and B photodiodes are formed in the pixel array unit P to sense R, G, and B signals.

Then, a portion of the interlayer dielectric layer 261 is selectively removed through a single damascene process, thereby forming a first via hole 271. Since an upper interconnection will be formed by burying a metal, the first via hole 271 is made to a depth of about 3000 Å to 5000 Å. The first via hole 271 may also be prepared in the form of a trench.

In addition, a dual damascene process can be applied to form a trench over a via hole through a photolithography process. That is, after forming the via hole, a wider area around the via hole is selectively removed to form a trench. Alternatively, after forming a trench, a via hole having a smaller width may be formed, giving the upper interconnection a two tier shape.

Next, as shown in FIG. 4B, a metal 274 is deposited over interlayer dielectric layer 261 to a sufficient depth to at least completely fill the first via hole. The metal may include copper, aluminum, etc. Tungsten W suitable for the damascene process may also be buried in the via hole.

Next, as shown in FIG. 4C, the entire surface of the resultant structure is planarized through the CMP process to form the upper interconnection 253 in the via hole 271. The surface of the interlayer dielectric layer 261 serves as a polish stop layer for the CMP process. Although not shown in the drawing, the upper interconnection 253 may be electrically connected through a contact plug to points in the lower interconnection layers 251 and 252.

The upper interconnection 253 is confined in the logic circuit area and is made thicker than the lower interconnections to reduce resistance.

Thus, when the interconnection has a three layer structure, two metal interconnection layers are formed in the pixel array area and three metal interconnection layers are formed in the logic circuit area. The lowermost metal interconnection 251 may have a thickness of about 1500 Å to 2500 Å, the intermediate metal interconnection layer 252 may have a thickness of about 2500 Å to 4000 Å, and the uppermost metal interconnection layer confined in the logic circuit area may have a thickness of about 5000 Å to 9000 Å.

Since the upper interconnection metal layer is buried in the interlayer dielectric layer through a damascene process, the problem of the step difference occurring between the pixel array area and the logic circuit area due to the height of the upper interconnection metal layer is solved.

After that, a first oxide layer 262 is formed over the entire surface of the upper interconnection metal layer 253. It is also possible to reduce the thickness of the first oxide layer 262 by a predetermined amount to reduce the step difference.

Then, a nitride layer 263 and a second oxide layer 264 are formed over the first oxide layer 262. The first oxide layer, the nitride layer and the second oxide layer constitute a protective layer 265 having a thickness of about 7000 Å.

In other situations, other protective layers may have a thickness of about 14000 Å to 17000 Å. To reduce the step difference, however, according to embodiments, the protective layer may have a thickness of about 6000 Å to 8000 Å, because it is possible to reduce the thickness of the protective layer. Thus, the thickness of the protective layer according embodiments corresponds to about half of the thickness of other protective layers.

After that, a micro-lens is formed over the protective layer 265 of the pixel array area. Since the thickness of the protective layer can be reduced as mentioned above, the vertical height of the micro-lens in the light receiving area can be significantly decreased, improving the sensitivity of the image sensor.

Finally, as shown in FIG. 4D, the protective layer 265 formed over the upper interconnection 253 is etched to form a second via hole 272 exposing the metal interconnection for power supply. The metal interconnection 253 is electrically connected to an external driving circuit through the second via hole, thereby completing the CMOS image sensor.

The method of manufacturing the CMOS image sensor according to embodiments has following advantages.

First, since the uppermost metal interconnection is formed on the interlayer dielectric layer through a damascene process, it is possible to reduce the thickness of the protective layer.

In addition, since the protective layer is formed with a minimum thickness, the vertical height of the micro-lens in the light receiving unit can be significantly reduced, so that the sensitivity of the image sensor is improved and the optical cross-talk can be reduced.

While the upper interconnection 253 may be described in the singular, a person skilled in the art will recognize that this interconnection may comprise several pad electrodes in the same layer. While the upper interconnection 253 may be described as connecting a power supply, a person skilled in the art will recognize that this interconnection layer may serve to provide all external connections to the CMOS image sensor, including power, ground, signal connections (for example, red, green, and blue data), control connections (for example, address, reset), etc.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method of manufacturing a CMOS image sensor comprising:
preparing a semiconductor substrate divided into a pixel array area and a logic circuit area;
forming a lower interconnection over the semiconductor substrate;
forming an interlayer dielectric layer over an entire surface of the semiconductor substrate including the lower interconnection;
forming a first via hole by removing a portion of the interlayer dielectric layer in the logic circuit area;
forming an upper interconnection by filling the first via hole with a metal;
planarizing a surface of the metal filling the first via hole.

2. The method as claimed in claim 1, wherein the first via hole is formed through a single damascene process.

3. The method as claimed in claim 1, wherein the first via hole is formed through a dual damascene process.

4. The method as claimed in claim 1, wherein the first via hole has a depth in a range of 3000 Å to 5000 Å.

5. The method as claimed in claim 1, further comprising:
forming a protective layer over the entire surface of the semiconductor substrate including the upper interconnection; and
forming a second via hole by removing a portion of the protective layer formed over the upper interconnection.

6. The method as claimed in claim 5, wherein the protective layer has a thickness in a range between 6000 Å to 8000 Å.

7. The method as claimed in claim 5, wherein the protective layer is formed by stacking a first oxide layer, a nitride layer, and a second oxide layer.

8. The method as claimed in claim 5, wherein the upper interconnection is connected to an external driving circuit through the second via hole.

9. The method as claimed in claim 5, further comprising a step of forming a micro-lens over the protective layer of the pixel array unit.

10. The method as claimed in claim 1, further comprising:
forming a photodiode over the semiconductor substrate.

11. The method as claimed in claim 1, wherein the lower interconnection has a multi-layer structure.

12. The method as claimed in claim 1, wherein the upper interconnection is electrically connected to the lower interconnection through a contact plug.

13. The method as claimed in claim 1, wherein the metal comprises tungsten (W).

14. The method as claimed in claim 1, wherein the step of burying the metal in the first via hole and planarizing the surface of the metal is achieved through a chemical mechanical polishing (CMP) process.

15. The method as claimed in claim 1, wherein the upper interconnection has a thickness of about 5000 Å to 9000 Å.

16. A method of manufacturing a CMOS image sensor comprising:
preparing a semiconductor substrate divided into a pixel array area and a logic circuit area;
forming a lower interconnection having a thickness of 1500 Å to 4000 Å over the semiconductor substrate;
forming an interlayer dielectric layer over an entire surface of the semiconductor substrate including the lower interconnection;
forming a first via hole by removing a portion of the interlayer dielectric layer in the logic circuit area;
forming an upper interconnection for a power supply by burying a metal in the first via hole and then planarizing a surface of the metal buried in the first via hole;
forming a protective layer over the entire surface of the semiconductor substrate including the upper interconnection; and forming a second via hole by selectively removing the protective layer formed over the upper interconnection.

17. The method as claimed in claim 16, wherein the protective layer has a thickness in a range of 6000 Å to 8000 Å.
